(19) United States
(12) Patent Application Publication
(10) Pub. No.: US 2021/0258001 A1
(43) Pub. Date: Aug. 19, 2021

(54) HIGH PERFORMANCE CMOS DIVIDE-BY-2

(71) Applicant: BAE SYSTEMS Information and Electronic Systems Integration Inc., Nashua, NH (US)

(72) Inventor: Gary M. Madison, Waltham, MA (US)

(73) Assignee: BAE SYSTEMS Information and Electronic Systems Integration Inc., Nashua, NH (US)

(21) Appl. No.: 16/571,620

(22) Filed: Sep. 16, 2019

(51) Int. Cl. H03K 5/00; H03K 3/037

(52) U.S. Cl. CPC H03K 5/00006; H03K 3/037

(57) ABSTRACT

A CMOS divide by two circuit device comprising a two phase signal input, a first track and hold circuit, a second track and hold circuit, where the signal path from input to output of each track and hold circuit comprises a single switch and a single inverter. In hold mode the circuit device provides cross-coupled inverters with only two stable states, obviating the need for any dedicated start-up, initialization, or phase-forcing circuitry. In addition to its regular two-phase output, it can optionally provide a quadrature two-phase output, both having an output signal frequency equal to one half said input signal frequency.

### STATEMENT OF GOVERNMENT INTEREST

This invention was made with government support under Prime Contract Number N00019-16-C-0033, Sub Contract Number 6533773795, awarded by the U.S. Navy. The United States Government has certain rights in the inventions.

### FIELD OF THE DISCLOSURE

This disclosure relates to signal processing, and, more particularly, to frequency dividers.

### BACKGROUND

Frequency dividers are used in frequency synthesizers for many applications including test and measurement equipment. One of the most basic of these is a divide-by-2. Some applications of the latter also require quadrature outputs. However, conventional divide-by-2 circuits typically have at least two gate delays in their-track-and-hold circuits, and many also require complex initialization and phase forcing circuitry to avoid unwanted modes, compromising speed, power and space. What is needed is a device, method, and system for a divide-by-2 capability operating at higher speeds, while consuming minimal space and power.

### SUMMARY

An embodiment provides a CMOS divide-by-2 circuit device comprising a two phase input signal input having an input signal frequency; a first track and hold circuit coupled to the two phase input signal; a second track and hold circuit coupled to the two phase input signal; a two phase output signal having an output signal frequency equal to about one half of the input signal frequency; wherein all signal paths from input to output within the first and second track and hold circuit comprise a single switch and a single inverter; wherein in a hold mode, wherein hold switches are turned on, the circuit device provides cross-coupled inverters with only two stable states. In embodiments the device is a static CMOS divide-by-2 circuit. In other embodiments, the output signal comprises in-phase and quadrature output signals. In subsequent embodiments the device operates at an input frequency of up to 70 GHz, and up to 100 degrees Centigrade. For additional embodiments, the first and second track-and-hold circuits, when in hold mode, operate as two cross-coupled inverters with only two stable states, low-high or high-low. In another embodiment, power consumption is approximately 150 micro watts per GHz at 100 degrees C. A following embodiment comprises using inverting feedback from an output of the second track and hold circuit to an input of the first track and hold circuit. In subsequent embodiments the first track and hold circuit and the second track and hold circuit comprise a high-speed, low-power, static edge-triggered D-latch. In additional embodiments the device includes no dedicated start-up or initialization circuitry. In included embodiments a configuration of the device includes no phase-forcing circuitry. In yet further embodiments the signal paths from input to output through each track and hold circuit consist of only one switch and one inverter, whereby delay is minimized. In related embodiments hold switch size reduction results in reduced circuit capacitance and overall size reduction which, in turn, contributes to a speed improvement and power reduction. For further embodiments, interconnections comprise a clk_p first input providing input to a hld_n input of the first track and hold circuit and to a hld_p input of the second track and hold circuit; a clk_n second input providing input to a hld_p input of the first track and hold circuit and to a hld_n input of the second track and hold circuit, wherein the inputs to hld_p input and hld_n input of the first track and hold comprise reverse phases; a first track and hold circuit Q_P output providing input to a D_P input of the second track and hold circuit; a first track and hold circuit Q_N output providing input to a D_N input of the second track and hold circuit; a second track and hold circuit Q_P output providing input to a D_N input of the first track and hold circuit; a second track and hold circuit Q_N output providing input to a D_P input of the first track and hold circuit, wherein the inputs to D_P and D_N of the first track and hold comprise reverse phases; output from the Q_P of the first track and hold providing the input to the D_P of the second track and hold providing a first output; and output from the Q_N of the first track and hold providing input to the D_N of the second track and hold providing a second output, wherein the first output and the second output comprise a two-phase output. In ensuing embodiments interconnections further comprise the output of the Q_P of the second track and hold providing the input to the D_N of the first track and hold providing a third output; and the output of the Q_N of the second track and hold providing the input to the D_P of the first track and hold providing a fourth output, wherein the third output and the fourth output comprise a quadrature two-phase output.

Another embodiment provides a method for dividing an input signal by two comprising providing the input signal having an input signal frequency; inverting the input signal; inputting an output from a second track and hold function to an input of a first track and hold function, whereby inverted feedback is provided, wherein all signal paths from input to output within each the track and hold circuit comprise a single switch and a single inverter, and, when in hold mode, having only two stable states; and outputting an output signal having an output signal frequency equal to one half of the input signal frequency. For yet further embodiments, the input comprises a two-phase input. For more embodiments, the outputs comprise both a two-phase output and a quadrature two-phase output. Continued embodiments include outputs of a second track and hold circuit providing inputs to a first track and hold circuit, wherein the inputs of the first track and hold comprise reverse phases. For additional embodiments the input signal frequency is up to 70 GHz.

A yet further embodiment provides a frequency divider for dividing an input signal by two comprising providing a 0 and 180 degree two-phase input signal input having an input signal frequency; a first track and hold circuit; a second track and hold circuit; wherein all signal paths from input to output within each track and hold circuit comprise a single switch and a single inverter; wherein, in hold mode, hold switches are turned on, the circuit device provides cross-coupled inverters with only two stable states; and wherein the first track and hold circuit comprises a single first switch and a single first inverter; wherein the second track and hold circuit comprises a single second switch and a single second inverter; inverting the input signal; inputting an output from a second track and hold function to an input of a first track and hold function, whereby inverted feedback is provided, wherein all signal paths from input to output within each the track and hold circuit comprise a single switch and a single inverter, and, when in hold mode, having only two stable states; and outputting a full, 90 degrees with respect to the original two phase outputs, quadrature output signal having an output signal frequency equal to one half of the input signal frequency.

### BRIEF DESCRIPTION OF THE DRAWINGS

FIG. 1 is a block diagram illustrating a CMOS divide-by-2 device configured in accordance with an embodiment.

FIG. 2 is a CMOS divide-by-2 top schematic configured in accordance with an embodiment.

FIG. 3 is a CMOS divide-by-2 track and hold schematic configured in accordance with an embodiment.

FIG. 4 depicts several schematic embodiments, namely CMOS_inv_x2, CMOS_sw_x2, and CMOS_sw_min.

FIG. 5 is a flow chart depicting a method configured in accordance with an embodiment.

FIG. 6 depicts CMOS divide-by-2 waveforms at 20 GHz configured in accordance with an embodiment.

FIG. 7 depicts CMOS divide-by-2 waveforms at 70 GHz configured in accordance with an embodiment.

FIG. 8 depicts CMOS divide-by-2 current consumption vs drive frequency configured in accordance with an embodiment.

These and other features of the present embodiments will be understood better by reading the following detailed description, taken together with the figures herein described. The accompanying drawings are not intended to be drawn to scale. For purposes of clarity, not every component may be labeled in every drawing.

### DETAILED DESCRIPTION

The features and advantages described herein are not all-inclusive and, in particular, many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The invention is susceptible of many embodiments. What follows is illustrative, but not exhaustive, of the scope of the invention.

Embodiments comprise a static CMOS divide-by-2 circuit with full quadrature outputs, that (process dependent) can operate up to 70 GHz and consume only about 150 μW/GHz, at 100 degrees C. Embodiments use two track-and-hold (TH) circuits with inverting feedback from the output of the second track and hold circuit to the input of the first track and hold circuit. The track and hold circuit topology takes advantage of a 2-phase input (0 and 180 degrees) to simultaneously achieve minimum delay (maximum speed) and immunity from unwanted modes. The latter quality obviates any need for special startup or power hungry phase-forcing circuitry. The track-and-hold input-to-output signal path consists of only one switch and one inverter, for minimum delay. The hold switch, carrying almost no current, needs only minimum size devices, for minimum added circuit capacitance. This achieves the maximum speed permitted by the process. In hold mode, the circuit looks like two cross-coupled inverters with only two stable states, low-high or high-low. Hence, there is no need for any added circuitry (initialization or phase-forcing) to prevent both inputs or outputs from ending up high or low.

The two track-and-holds, without feedback, could be used to make a very fast, low-power static edge-triggered D-latch.

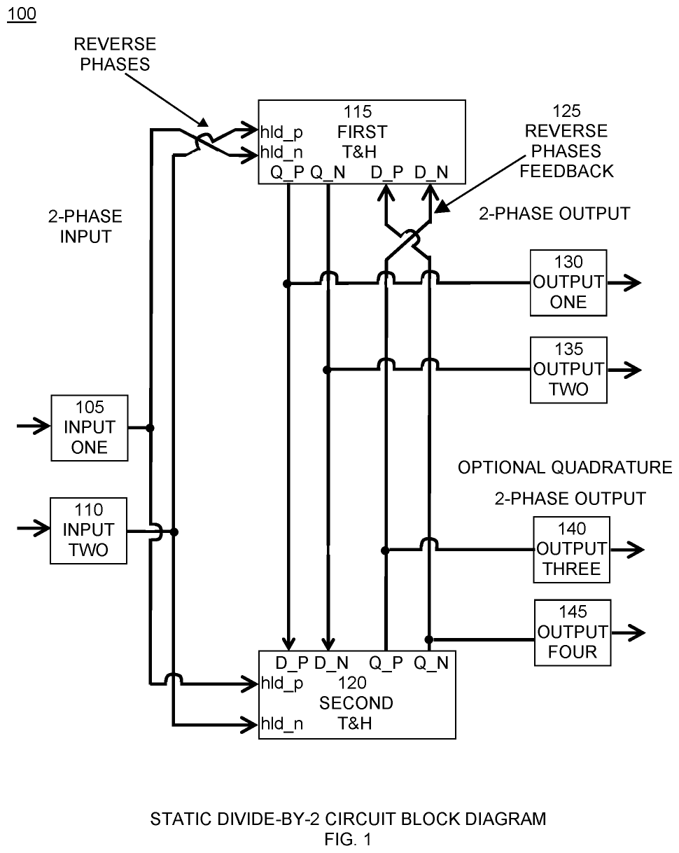

FIG. 1 is block diagram 100 illustrating a CMOS divide-by-2 device. In this example there are two inputs, input one 105 and input two 110. In embodiments the initial input signal can be a 2-phase input signal or be separated into a 2-phase input signal by a phase divider (not shown). Together, the phase shifted input one 105 and input two 110 comprise a two-phase (180 degree) input signal to two track and hold circuits, first track and hold circuit 115 and second track and hold circuit 120 which provides reverse phase feedback 125. Output comprises at least a two-phase output, namely, output one 130 and output two 135. In one example, an optional quadrature 2-phase output is also generated, including output three 140 and output four 145.

In this example, input one is coupled to the hld_n of the first track-and-hold circuit 115 and the hld_p of the second track-and-hold circuit 120. Likewise, input two is coupled to the hld_p of the first track-and-hold circuit 115 and the hld_n of the second track-and-hold circuit 120. Within each track-and-hold, the hold switch, carrying almost no current, needs only minimum size devices, for minimum added circuit capacitance. This achieves the maximum speed permitted by the process. In hold mode, the circuit looks like two cross-coupled inverters with only two stable states, low-high or high-low. Hence, there is no need for any added circuitry (initialization or phase-forcing) to prevent both inputs or outputs from ending up high or low. A track and hold circuit is device that follows a signal during the tracking phase. It STORES AND accurately represents that signal as a valid output during the hold phase. In this example, the track-and-hold input-to-output signal path consists of only one switch and one inverter, for minimum delay.

Inputs to hld_p and hld_n of First T&H 115 comprise reverse phases. First T&H 115 Q_P provides input to D_P of Second T&H 120. First T&H 115 Q_N provides input to D_N of Second T&H 120. Second T&H 120 Q_P provides input to D_N of First T&H 115. Second T&H 120 Q_N provides input to D_P of First T&H 115. Inputs to D_P and D_N of First T&H 115 comprise reverse phases 125. Output from Q_P of First T&H 115 providing input to D_P of Second T&H 120 provides Output One 130. Output from Q_N of First T&H 115 providing input to D_N of Second T&H 120 provides Output Two 135. Output Q_P of Second T&H 120 providing input to D_N of First T&H 115 provides Output Three 140. Output Q_N of Second T&H 120 providing input to D_P of First T&H 115 provides Output Four 145. Output One 130 and Output Two 135 provide a 2-phase output. Output Three 140 and Output Four 145 provide optional quadrature 2-phase output.

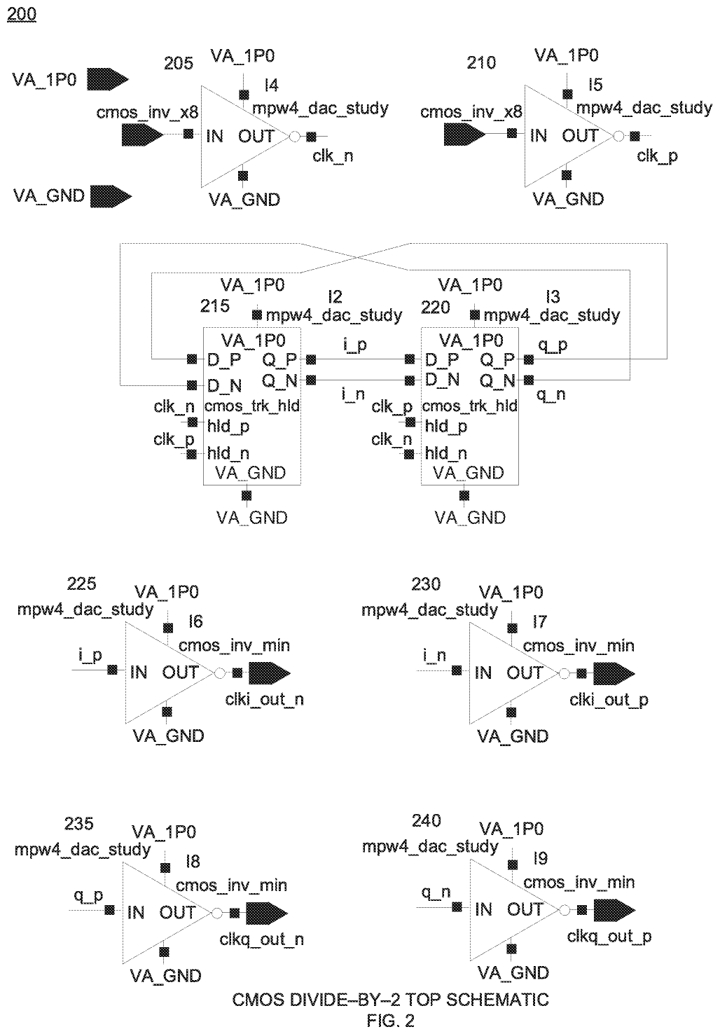

FIG. 2 is a CMOS divide-by-2 top schematic 200. Components comprise a first CMOS inverter 205; a second CMOS inverter 210; first CMOS track and hold (TH) 215; second CMOS track and hold 220; first output CMOS inverter 225; second output CMOS inverter 230; third output CMOS inverter 235; and fourth output CMOS inverter 240. In embodiments, interconnections comprise clk_n input to hld_p of First T&H 215 and to hld_n of Second T&H 220. clk_p is input to hld_n of First T&H 215 and to hld_p of Second T&H 220. Inputs to hld_p and hld_n of First T&H 215 comprise reverse phases. Continuing, First T&H 215 Q_P provides input to D_P of Second T&H 220. First T&H 225 Q_N provides input to D_N of Second T&H 220. Second T&H 220 Q_P provides input to D_N of First T&H 215. Second T&H 220 Q_N provides input to D_P of First T&H 215. Inputs to D_P and D_N of First T&H 215 comprise reverse phases. Output from Q_P of First T&H 215 providing input to D_P of Second T&H 220 provides Output One. Output from Q_N of First T&H 215 providing input to D_N of Second T&H 220 provides Output Two. Output Q_P of Second T&H 220 providing input to D_N of First T&H 215 provides Output Three. Output Q_N of Second T&H 220 providing input to D_P of First T&H 215 provides Output Four. Output One and Output Two provide a 2-phase output. Output Three and Output Four provide optional quadrature 2-phase output.

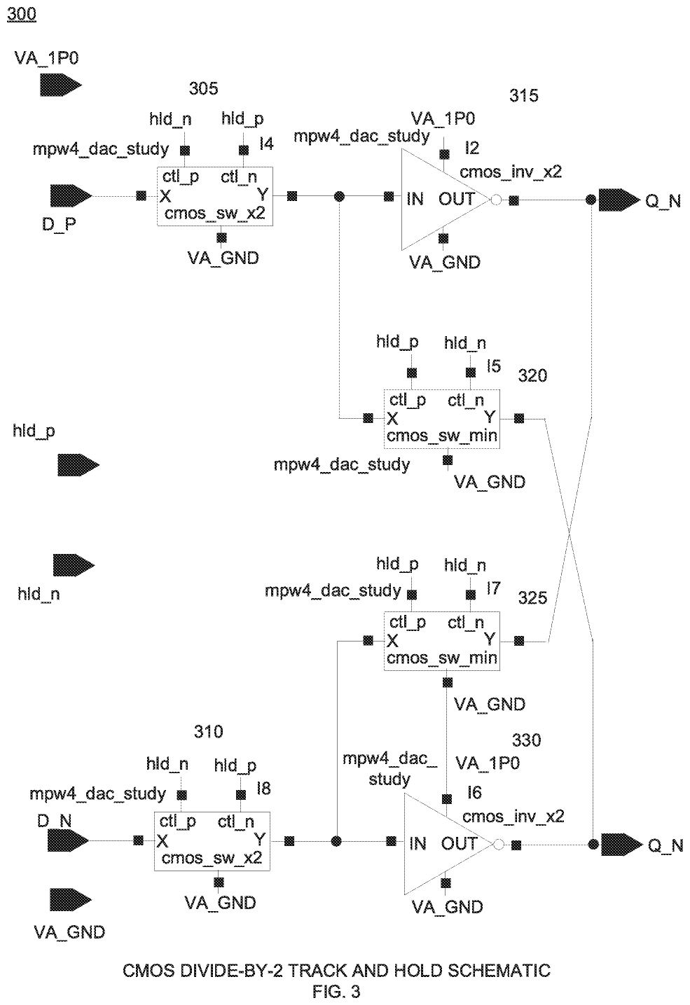

FIG. 3 is a CMOS divide-by-2 track and hold schematic 300. Components comprise first input CMOS switch_x2 305; second input CMOS switch_x2 310; first CMOS inverter_x2 315; first CMOS hold switch_min 320; second CMOS hold switch_min 325, and second CMOS inverter_x2 330. In embodiments, interconnections comprise input D_P to first input CMOS switch_x2 305 with first input CMOS switch_x2 305 output to input of first CMOS inverter_x2 315 providing output Q_N. Input D_N to second input CMOS switch_x2 310 with second input CMOS switch_x2 310 output to input of second CMOS inverter_x2 330 provides output Q_P. Input to first CMOS inverter_x2 315 is also input to first CMOS hold switch_min 320. First CMOS hold switch_min 320 output is also connected to Q_P. Input to second CMOS inverter_x2 330 is also input to second CMOS hold switch_min 325. Second CMOS hold switch_min 325 output is also connected to Q_N.

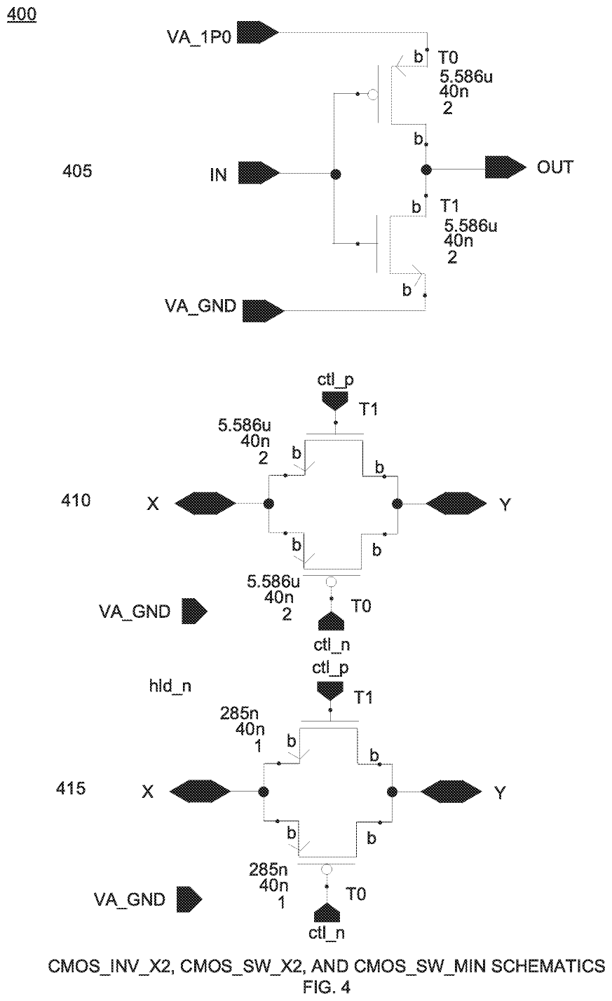

FIG. 4 depicts CMOS_inv_x2, CMOS_sw_x2, and CMOS_sw_min schematics 400. Particularly, CMOS_inv_x2 405, CMOS_sw_x2 410, and CMOS_sw_min 415. In embodiments, interconnections comprise CMOS_inv_x2 405 having inputs VA_1P0, IN, and VA_GND, and output OUT. CMOS_sw_x2 410 interconnections comprise x, y, ctl_p, and ctl_n. CMOS_sw_min 415 interconnections comprise x, y, ctl_p, and ctl_n.

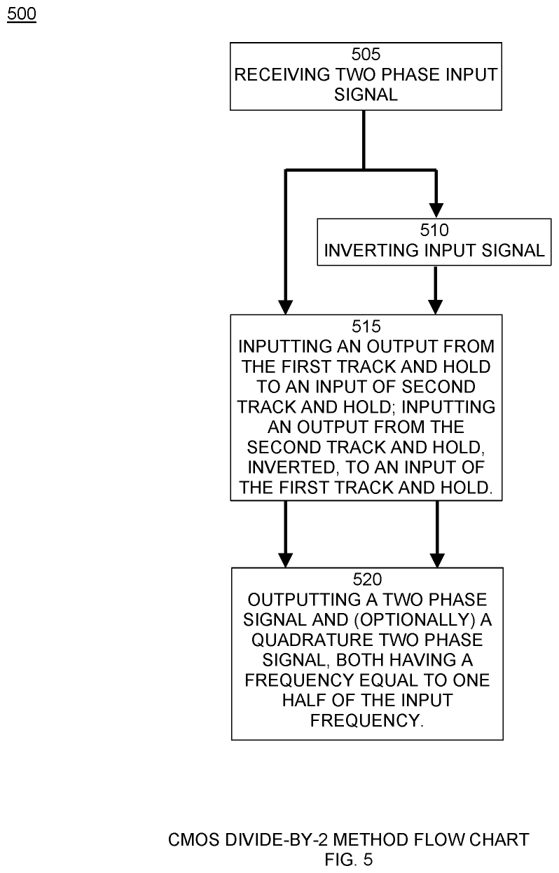

FIG. 5 is a flow chart depicting a method 500 according to one example. Steps comprise receiving a two phase input signal 505. In embodiments, this can be two separate phase shifted signals from two sources or a signal that is coupled to a phase shifter to provide two phase shifted input signals. Processing involves inverting the input signal 510, in this differential system this is accomplished solely by reversing the _P and _N leads without adding additional circuitry. The technique continues by inputting an output from the first track and hold to an input of second track and hold circuit and inputting an output from the second track and hold, inverted, to an input of the first track and hold 515. The output is a differential in-phase and (optionally) a quadrature two-phase signal, both having a frequency equal to one-half the input signal frequency 520.

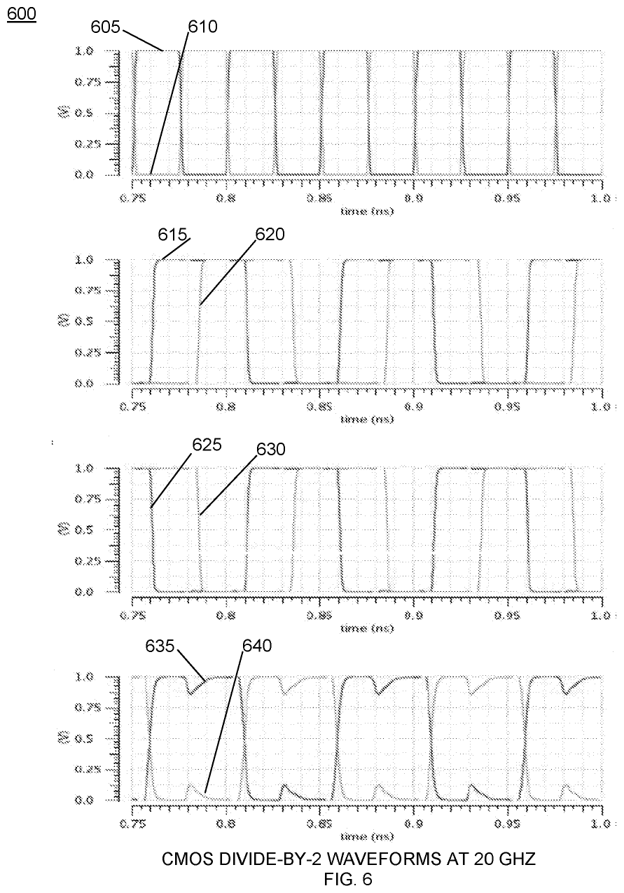

FIG. 6 depicts CMOS divide-by-2 transient analysis waveforms at 20 GHz 600. Depicted are 20 GHz clkin_p 605 and clkin_n 610; Output _p Signals clki_out_p 615 and clkq_out_p 620; Output _n Signals clki_out_n 625 and clkq_out_n 630; and Internal Nodes i_p 635 and i_n 640. The voltage scale is 0 to 1.0 volts, and the time scale is from 0.75 ns to 1.0 ns. Accurate waveforms are evident at these frequencies.

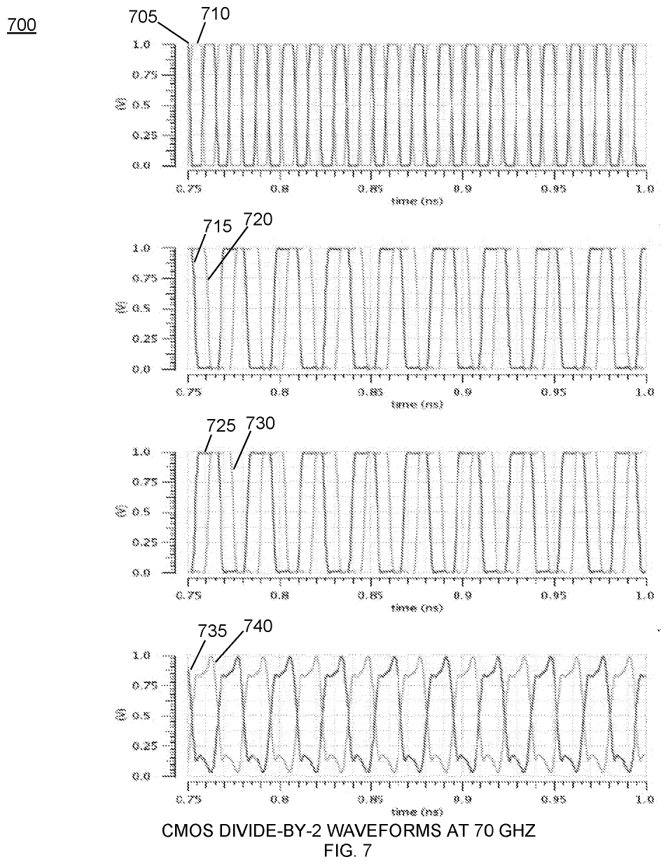

FIG. 7 depicts CMOS divide-by-2 waveforms at 70 GHz 700. Depicted are 70 GHz clkin_p 705 and clkin_n 710; Output _p Signals clki_out_p 715 and clkq_out_p 720; Output _n Signals clki_out_n 725 and clkq_out_n 730; and Internal Nodes i_p 735 and i_n 740. The voltage scale is 0 to 1.0 volts, and the time scale is from 0.75 ns to 1.0 ns. Accurate waveforms are evident at even these frequencies, especially input versus output.

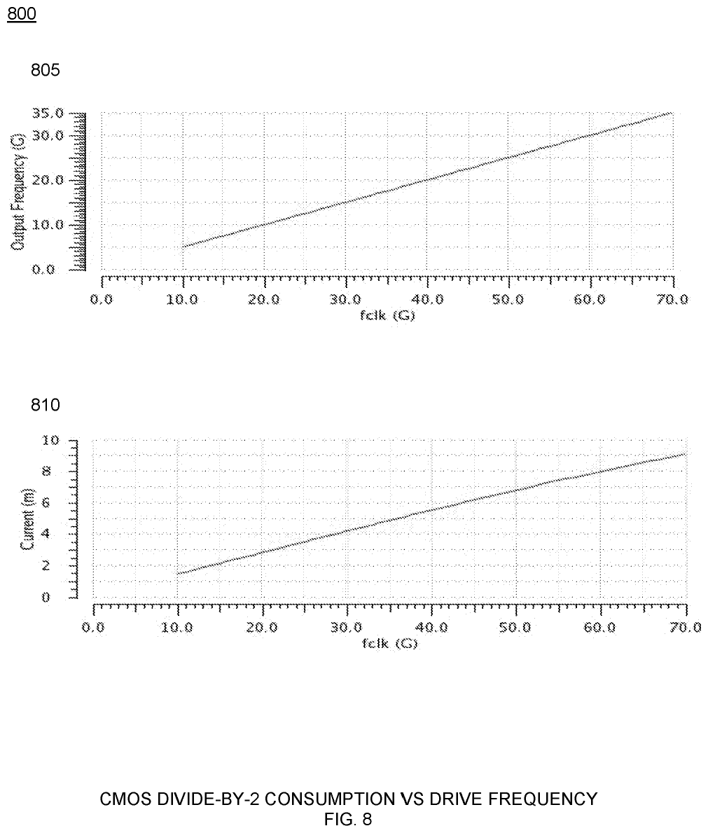

FIG. 8 depicts CMOS divide-by-2 current consumption vs drive frequency 800. Output frequency 805 is depicted for input frequencies of 10 GHz to 70 GHz. At an fclk of 10 GHz, the output frequency is 5 GHz progressing linearly to, at an fclk of 70 GHz, an output frequency of 35 GHz. Current consumption 810 is depicted over the 10 GHz to 70 GHz range. At an fclk of 10 GHz, current consumption is 1.5 milliamps progressing linearly to, at an fclk of 70 GHz, a current consumption of 9 milliamps.

The flowchart and block diagrams in the Figures illustrate the architecture, functionality, and operation of possible implementations of systems, methods, according to various embodiments of the present invention.

The foregoing description of the embodiments has been presented for the purposes of illustration and description. It is not intended to be exhaustive or to limit the invention to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

Each and every page of this submission, and all contents thereon, however characterized, identified, or numbered, is considered a substantive part of this application for all purposes, irrespective of form or placement within the application. This specification is not intended to be exhaustive or to limit the invention to the precise form disclosed. Many modifications and variations are possible in light of this disclosure. Other and various embodiments will be readily apparent to those skilled in the art, from this description, figures, and the claims that follow. It is intended that the scope of the invention be limited not by this detailed description, but rather by the claims appended hereto.

1. A CMOS divide-by-2 circuit device comprising:
a two phase input signal input having an input signal frequency;
two track and hold circuits coupled to each other;
a first track and hold circuit coupled to the two phase input signal, the first track and hold circuit comprising a pair of first CMOS switches, a pair of first hold switches and a pair of first inverters;
a second track and hold circuit coupled to the two phase input signal, the second track and hold circuit comprising a pair of second CMOS switches, a pair of second hold switches and a pair of second inverters; and
a two phase output signal having an output signal frequency equal to about one half of said input signal frequency;
wherein for each of a track and hold input-to-output signal path, the first and second pair of CMOS switches are both turned on and the first and second pair of hold switches are both turned off, the first and second pair of inverters provide the two phase output signal such that each signal path only goes through a single CMOS switch and a single inverter;
wherein in a hold mode, the first and second pair of CMOS switches are both turned off and the first and second pair of hold switches are both turned on, the circuit device forms a pair of cross-coupled inverters such that each signal path only goes through a single hold switch and a single inverter providing an output with only two stable states.

2. The device of claim 1, wherein said device is a static CMOS divide-by-2 circuit.

3. The device of claim 1, wherein said output signal comprises in-phase and quadrature output signals.

4. The device of claim 1, wherein said device operates at said input frequency of up to 70 GHz and up to 100 degrees Centigrade.

5. The device of claim 1, wherein said first and second track and hold circuits, when in hold mode, operate as two cross-coupled inverters with only two stable states, low-high or high-low.

6. The device of claim 1, wherein power consumption is approximately 150 micro watts per GHz at 100 degrees C.

7. The device of claim 1, comprising using inverting feedback from an output of said second track and hold circuit to an input of said first track and hold circuit.

8. The device of claim 1, wherein said first track and hold circuit and said second track and hold circuit comprise a high-speed low-power static edge-triggered D-latch.

9. The device of claim 1, wherein said device includes no dedicated start-up or initialization circuitry.

10. The device of claim 1, wherein a configuration of said device includes no phase-forcing circuitry.

11. (canceled)

12. The device of claim 1, wherein hold switch size reduction results in reduced circuit capacitance and overall size reduction which, in turn, contributes to a speed improvement and power reduction.

13. The device of claim 1, wherein interconnections comprise:
a clk_p first input providing input to a hld_n input of said first track and hold circuit and to a hld_p input of said second track and hold circuit;
a clk_n second input providing input to a hld_p input of said first track and hold circuit and to a hld_n input of said second track and hold circuit, wherein said inputs to hld_p input and hld_n input of said first track and hold comprise reverse phases;
a first track and hold circuit Q_P output providing input to a D_P input of said second track and hold circuit;
a first track and hold circuit Q_N output providing input to a D_N input of said second track and hold circuit;
a second track and hold circuit Q_P output providing input to a D_N input of said first track and hold circuit;
a second track and hold circuit Q_N output providing input to a D_P input of said first track and hold circuit, wherein said inputs to D_P and D_N of said first track and hold comprise reverse phases;
output from said Q_P of said first track and hold providing said input to said D_P of said second track and hold providing a first output; and
output from said Q_N of said first track and hold providing input to said D_N of said second track and hold providing a second output, wherein said first output and said second output comprise a two-phase output,
wherein all signal paths from input to output within each of the first and the second track and hold circuit use a single switch and a single inverter.

14. The device of claim 13, wherein interconnections further comprise:
said output of said Q_P of said second track and hold providing said input to said D_N of said first track and hold providing a third output; and
said output of said Q_N of said second track and hold providing said input to said D_P of said first track and hold providing a fourth output, wherein said third output and said fourth output comprise a quadrature two-phase output.

15. A method for dividing an input signal by two comprising:
providing said input signal having an input signal frequency;
inverting said input signal;
providing two track and hold circuits coupled to each other, a first track and hold circuit comprising a pair of first switches, a pair of first hold switches and a pair of first inverters;
a second track and hold circuit, the second track and hold circuit comprising a pair of second switches, a pair of second hold switches and a pair of second inverters;
inputting an output from a second track and hold function to an input of a first track and hold function, whereby inverted feedback is provided, wherein all signal paths from input to output within each of said first and said second track and hold circuit use a single switch and a single inverter, and only when in hold mode, having only two stable states; and
outputting an output signal having an output signal frequency equal to one half of said input signal frequency.

16. The method of claim 15, wherein said input comprises a two-phase input.

17. The method of claim 15, wherein said outputs comprise both a two-phase output and a quadrature two-phase output.

18. The method of claim 15, wherein outputs of said second track and hold circuit provides inputs to said first track and hold circuit, wherein said inputs of said first track and hold comprise reverse phases.

19. The method of claim 15, wherein said input signal frequency is up to 70 GHz.

20. A frequency divider for dividing an input signal by two comprising:
providing:
a 0 and 180 degree two-phase input signal input having an input signal frequency;
a first track and hold circuit;
a second track and hold circuit;
wherein an input-to-output signal path within each of the first and the second track and hold circuit use a single switch and a single inverter;
wherein, in hold mode, wherein hold switches are turned on, said circuit device provides cross-coupled inverters with only two stable states; and
wherein a signal path of said first track and hold circuit comprises:
a single first hold switch and a single first inverter;
wherein a signal path of said second track and hold circuit comprises:
a single second hold switch and a single second inverter;
inverting said input signal;
inputting an output from a second track and hold function to an input of a first track and hold function, whereby inverted feedback is provided, wherein all signal paths from input to output within each said track and hold circuit comprise a single switch and a single inverter, and when in hold mode, having only two stable states; and
outputting a full, 90 degrees with respect to the original two phase outputs, quadrature output signal having an output signal frequency equal to one half said input signal frequency.

21. The device of claim 1, wherein a current consumption of the CMOS divide-by-2 circuit device versus drive frequency is selected from one of less than 2 mA up to 10 GHz, less than 3 mA up to 20 GHz, less than 7 mA up to 50 GHz and less than 9 mA up to 70 GHz.
